(19) United States
(12) Patent Application Publication
(10) Pub. No.: US 2025/0287666 A1
(43) Pub. Date: Sep. 11, 2025

(54) SEMICONDUCTOR DEVICE AND METHOD

(71) Applicant: Taiwan Semiconductor Manufacturing Co., Ltd., Hsinchu (TW)

(72) Inventors: Sih-Jie Liu, Hsinchu (TW); Liang-Yin Chen, Hsinchu (TW); Chien-Hao Chen, Chuangwei Township (TW)

(21) Appl. No.: 18/597,219

(22) Filed: Mar. 6, 2024

(51) Int. Cl. H01L 29/66; H01L 29/06; H01L 29/08; H01L 29/423; H01L 29/775

(52) U.S. Cl. CPC H10D 64/017; H10D 30/014; H10D 30/43; H10D 30/6735; H10D 62/121; H10D 62/151

(57) ABSTRACT

A semiconductor device and the method of forming the same are provided. The semiconductor device may include a substrate, a fin structure protruding from the substrate, an isolation region on the substrate and along a sidewall of the fin structure, a stack of nanostructures including a first nanostructure over the fin structure, a gate structure extending between nanostructures of the stack of nanostructures and around the first nanostructure, and a first source/drain region and a second source/drain region. The stack of nanostructures may be between the first source/drain region and the second source/drain region. An upper portion of the isolation region may include first dopants of a first noble gas element.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nanostructure field-effect transistors (nano-FETs) in a three-dimensional view, in accordance with some embodiments.

FIGS. 2, 3, 4, 5, 6A, 6B, 6C, 6D, 6E, 7A, 7B, 7C, 7D, 7E, 8A, 8B, 8C, 8D, 8E, 9A, 9B, 9C, 9D, 9E, 10A, 10B, 10C, 10D, 10E, 11A, 11B, 11C, 11D, 11E, 11F, 12A, 12B, 12C, 12D, 12E, 12F, 12G, 13A, 13B, 13C, 14A, 14B, 14C, 15A, 15B, 15C, 15D, 15E, 16A, 16B, 16C, 16D, 16E, 17A, 17B, 17C, 17D, 17E, 18A, 18B, 18C, 19A, 19B, 19C, 20A, 20B, and 20C are views of intermediate stages in the manufacturing of a semiconductor device including nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide methods of forming semiconductor devices with reduced risk of shorting between source/drain regions and gate structures. For example, some embodiments provide methods of forming nano-FETs that include reducing the widths of portions of dummy gate dielectrics by doping and etching processes before forming the source/drain regions and the gate structures. As a result, a risk of damaging the dummy gate dielectrics by subsequent etching processes may be decreased, protection on the source/drain regions may be increased, and a risk of shorting between the source/drain regions and the gate structures may be decreased. Therefore, the performance and reliability of the semiconductor devices may be improved.

Some embodiments discussed herein are described in the context of a semiconductor device including nano-FETs. However, various embodiments may be applied to dies including other types of transistors (e.g., fin field effect transistors (FinFETs), vertical field-effect transistors (VFETs), complementary field-effect transistors (CFETs), planar transistors, or the like) in lieu of or in combination with the nano-FETs.

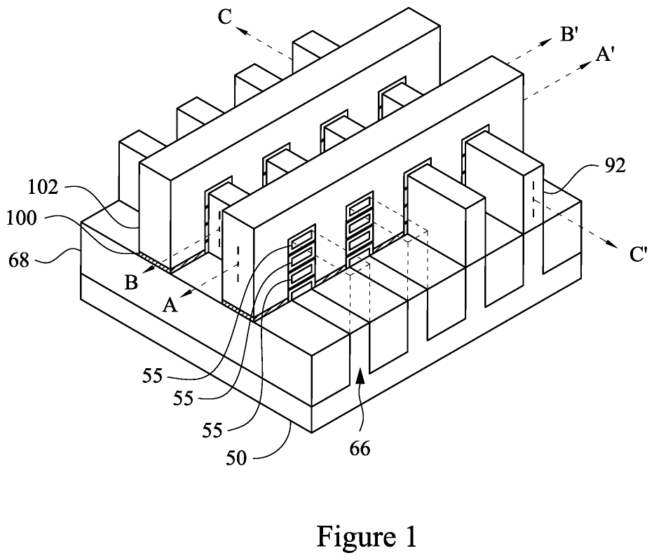

FIG. 1 illustrates an example of nano-FETs (e.g., nanowire FETs, nanosheet FETs, or the like) in a three-dimensional view. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Shallow trench isolation (STI) regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring STI regions 68. Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102.

FIG. 1 further illustrates reference cross-sections that are used in later figures. Reference cross-section A-A′ is along a longitudinal axis of a gate electrode 102 and in a direction, for example, perpendicular to the direction of current flow between the epitaxial source/drain regions 92 of a nano-FET. Reference cross-section B-B′ is parallel to the reference cross-section A-A′ and extends through epitaxial source/drain regions 92 of multiple nano-FETs. Reference cross-section C-C′ is perpendicular to the reference cross-section A-A′ and is parallel to a longitudinal axis of a fin 66 of the nano-FET and in a direction of, for example, a current flow between the epitaxial source/drain regions 92 of the nano-FET. Subsequent figures refer to these reference cross-sections for clarity. Some embodiments discussed herein are discussed in the context of nano-FETs formed using a gate-last process. In other embodiments, a gate-first process may be used. Also, some embodiments contemplate aspects used in planar devices, such as planar FETs or in FinFETs.

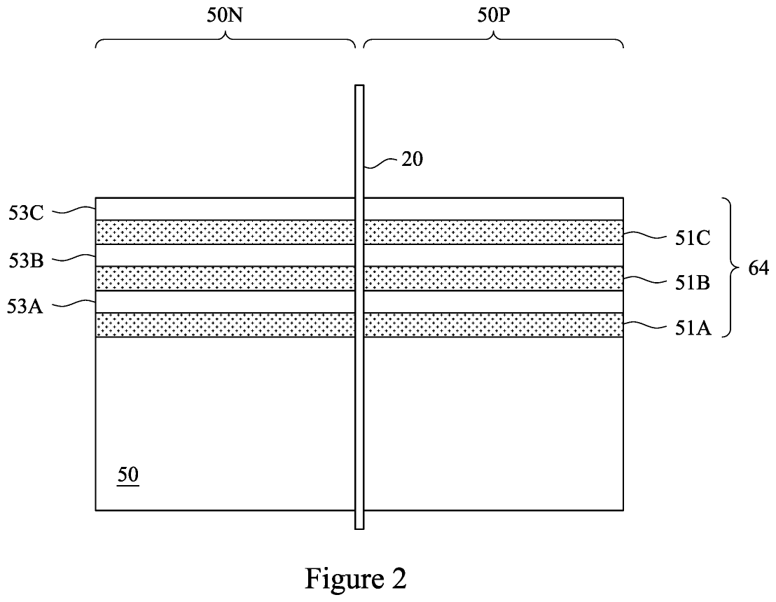

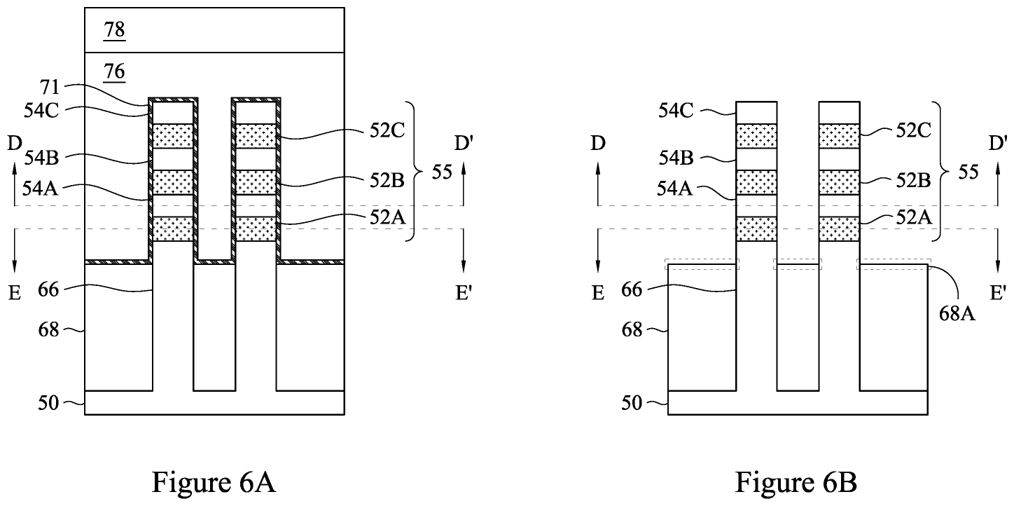

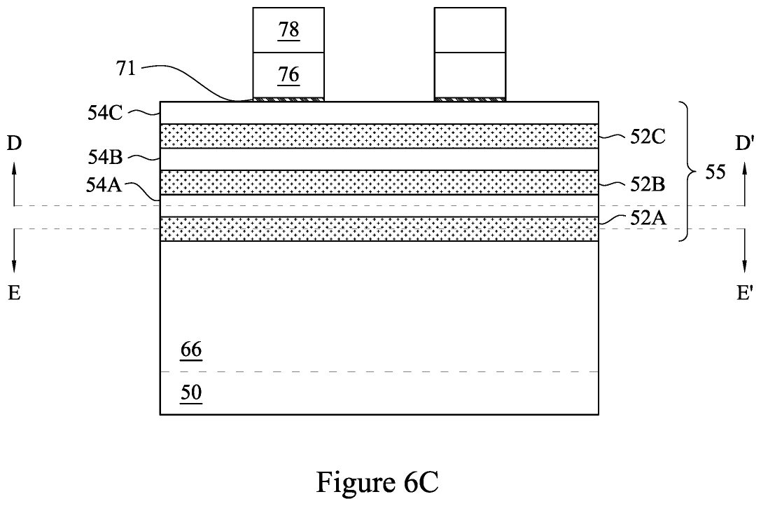

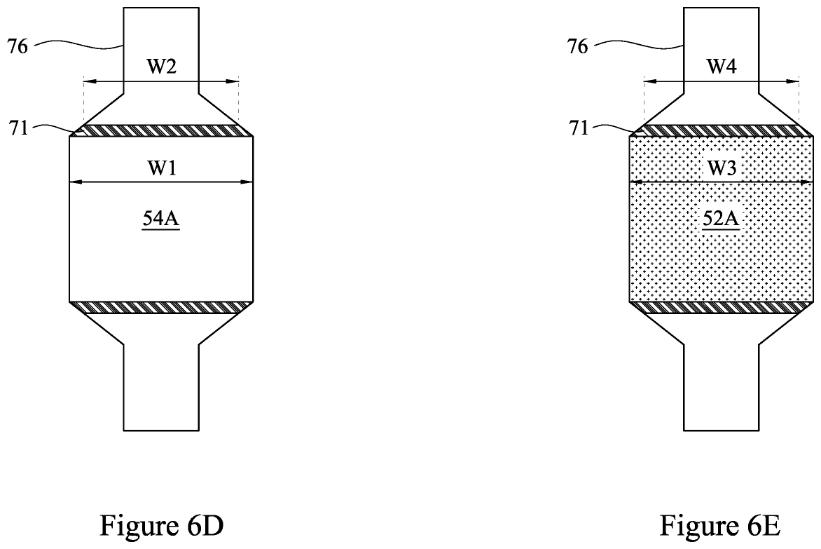

FIGS. 2 through 20C are views of intermediate stages in the manufacturing of a semiconductor device including nano-FETs, in accordance with some embodiments. FIGS. 2, 3, 4, 5, 6A, 7A, 8A, 9A, 10A, 11A, 12A, 13A, 14A, 15A, 16A, 17A, 18A, 19A, and 20A illustrate cross-sectional views along the reference cross-section A-A′ illustrated in FIG. 1. FIGS. 6B, 7B, 8B, 9B, 10B, 11B, 12B, 12F, 13B, 14B, 15B, 16B, 17B, 18B, 19B, and 20B illustrate cross-sectional views along the reference cross-section B-B′ illustrated in FIG. 1. FIGS. 6C, 7C, 8C, 9C, 10C, 11C, 11F, 12C, 12G, 13C, 14C, 15C, 16C, 17C, 18C, 19C, and 20C illustrate cross-sectional views along the reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). For purposes of illustration and as discussed in greater detail below, the first semiconductor layers 51 will be removed and the second semiconductor layers 53 will be patterned to form channel regions of nano-FETs in the n-type region 50N and the p-type region 50P. However, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In some embodiments the second semiconductor layers 53 may be removed and the first semiconductor layers 51 may be patterned to form channel regions of nano-FETs in the n-type region 50N, and the first semiconductor layers 51 may be removed and the second semiconductor layers 53 may be patterned to form channel regions of nano-FETs in the p-type region 50P. In some embodiments, the second semiconductor layers 53 may be removed and the first semiconductor layers 51 may be patterned to form channel regions of nano-FETs in both the n-type region 50N and the p-type region 50P.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium or the like, and the second semiconductor layers 53 may be formed of a second semiconductor material different from the first semiconductor material, such as silicon, carbon-doped silicon, or the like.

The first semiconductor materials and the second semiconductor materials may be materials having a high etch selectivity to one another. As such, the first semiconductor layers 51 of the first semiconductor material may be removed without significantly removing the second semiconductor layers 53 of the second semiconductor material thereby allowing the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material, thereby allowing the first semiconductor layers 51 to be patterned to form channel regions of nano-FETs.

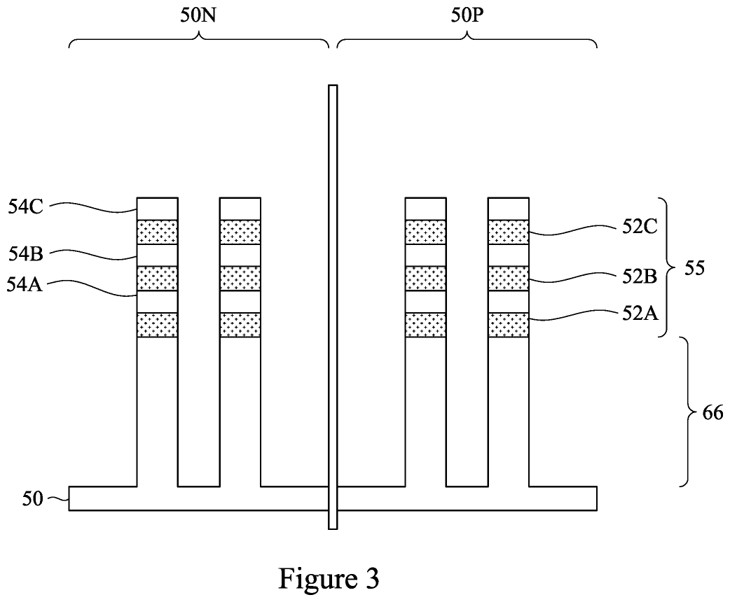

In FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

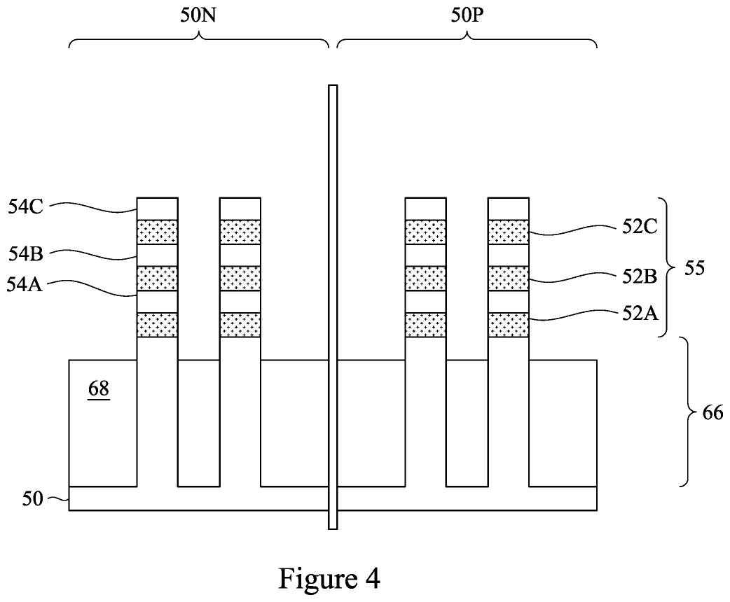

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material may be substantially co-planar or level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric acid may be used.

The process described above with respect to FIGS. 2 through 4 is one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes. In some embodiments, one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implantation, the photoresist may be removed, such as by an acceptable ashing process. After the implantations of the n-type region 50N and the p-type region 50P, an annealing may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

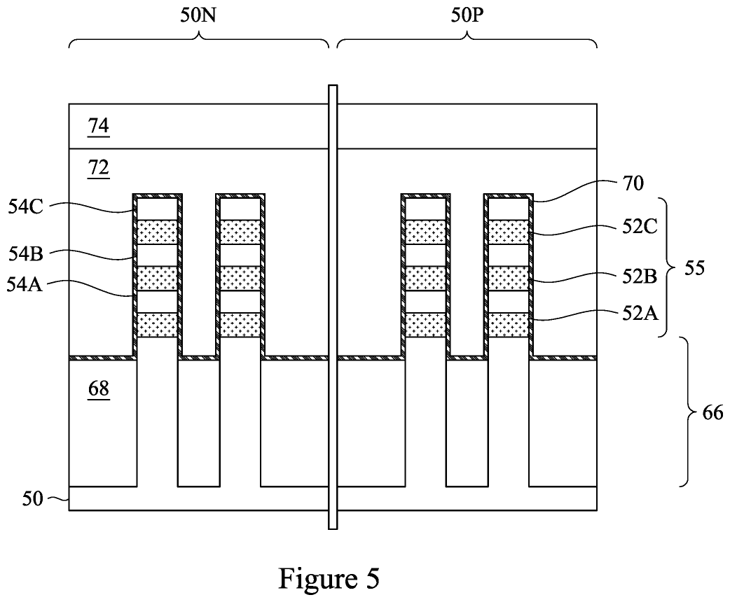

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering the fins 66, the nanostructures 55, and the STI regions 68 such that the dummy dielectric layer 70 extends between the dummy gate layer 72 and the STI regions 68 for illustrative purposes. In some embodiments, the dummy dielectric layer 70 may be formed such that the dummy dielectric layer 70 covers the fins 66 and the nanostructures 55, but not the STI regions 68.

FIGS. 6A through 20C illustrate various additional steps in the manufacturing of the nano-FET devices, in accordance to some embodiments. FIGS. 6A through 20C illustrate features in either or both the n-type region 50N or the p-type region 50P. In FIGS. 6A through 6E, masks 78, dummy gates 76, and dummy gate dielectrics 71 are formed. The dummy gates 76 and dummy gate dielectrics 71 may be collectively referred to as dummy gate structures. FIG. 6D illustrates a top-down view of a portion of the structures illustrated in FIGS. 6A, 6B, and 6C, including the second nanostructure 54A, along the reference cross-sections D-D′. FIG. 6E illustrates a top-down view of a portion of the structures illustrated in FIGS. 6A, 6B, and 6C, including the first nanostructure 52A, along the reference cross-sections E-E′. The following discussion uses the top-down view of the second nanostructure 54A as an example of the second nanostructures 54 and the top-down view of the first nanostructure 52A as an example as an example of the first nanostructures 52. Same or similar shapes, dimensions, and properties may also apply to other second nanostructures 54 and first nanostructures 52.

The mask layer 74 (see FIG. 5) may be patterned using suitable photolithography and etching processes to form the masks 78. The pattern of the masks 78 then may be transferred to the dummy gate layer 72 and to the dummy dielectric layer 70 to form the dummy gates 76 and the dummy gate dielectrics 71, respectively, using suitable etching processes. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

As shown in FIG. 6D, after the etching processes, the dummy gate dielectrics 71 between the dummy gates 76 and the second nanostructure 54A may have shapes of a trapezoid in the top-down view with tilted sidewalls exposed. The dummy gate dielectrics 71 may have a width W1 at an interface between the dummy gate dielectrics 71 and the second nanostructure 54A, and a width W2 at an interface between the dummy gate dielectrics 71 and the dummy gate 76. In some embodiments, the width W1 is larger than the width W2.

Similarly, as shown in FIG. 6E, after the etching processes, the dummy gate dielectrics 71 between the dummy gate 76 and the first nanostructure 52A may have shapes of a trapezoid in the top-down view with tilted sidewalls exposed. The dummy gate dielectrics 71 may have a width W3 at an interface between the dummy gate dielectrics 71 and the first nanostructure 52A, and a width W4 at an interface between the dummy gate dielectrics 71 and the dummy gate 76. In some embodiments, the width W3 is larger than the width W4. Portions of the dummy gates 76 in contact with the dummy gate dielectrics 71 may also have shapes of a trapezoid in the top-down view. Widths of the portions of the dummy gates 76 may decrease as the dummy gate 76 extends away from the second nanostructure 54A and/or the first nanostructure 52A.

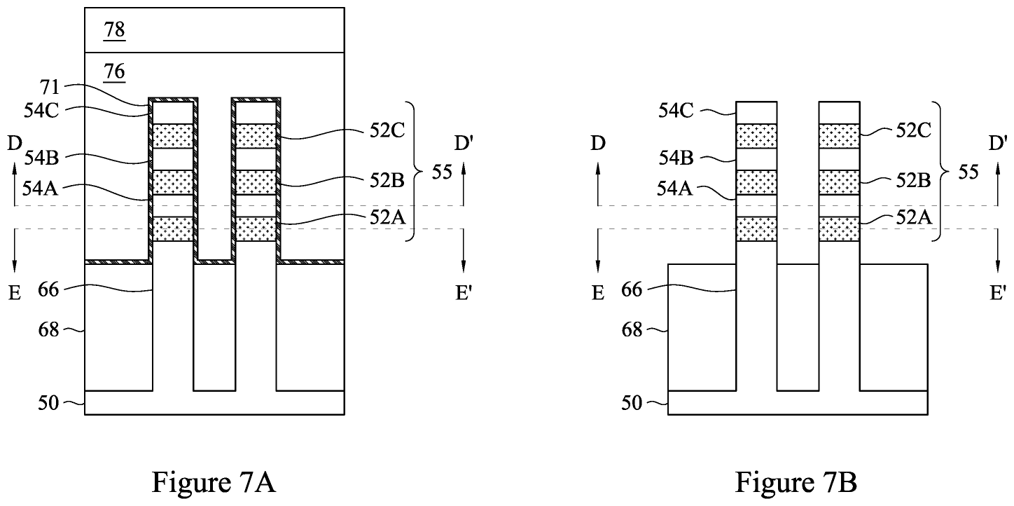

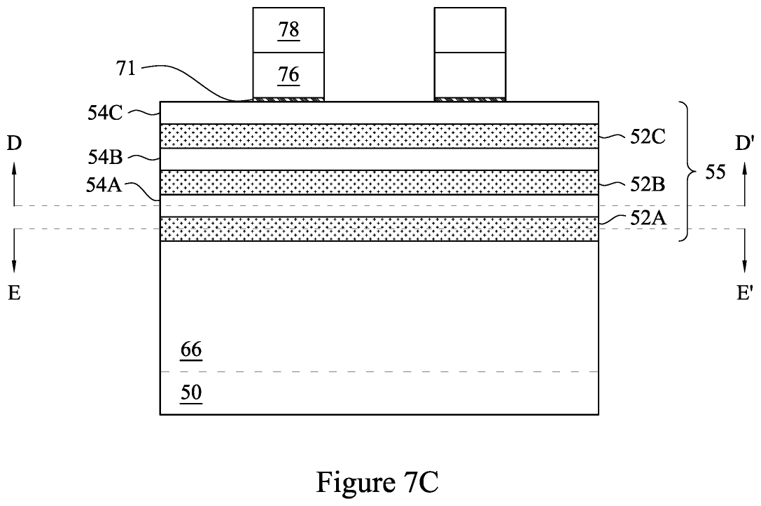

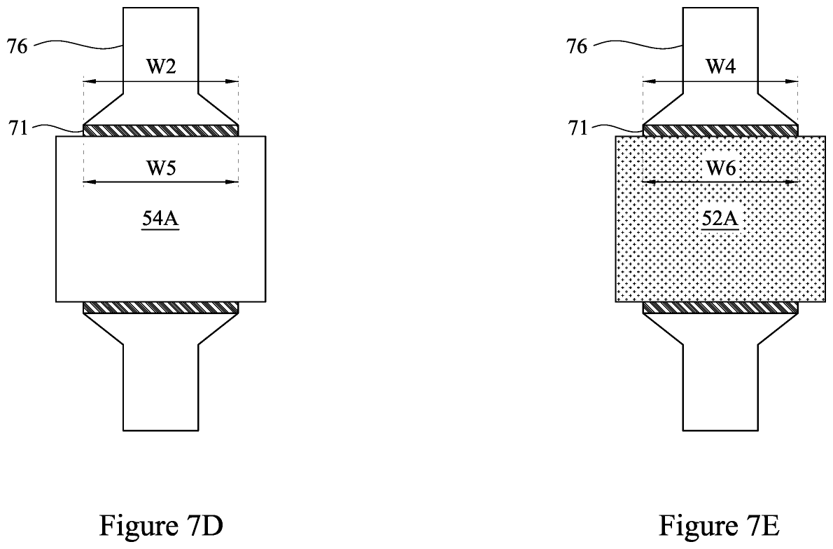

In FIGS. 7A through 7E, portions of the dummy gate dielectrics 71 adjacent the exposed tilted sidewalls are removed. As a result, the widths of the dummy gate dielectrics 71 in contact with the first nanostructure 52A and the second nanostructure 54A the may be reduced, which may decrease the risk of damaging the dummy gate dielectrics 71 by subsequent etching processes, improve protection on subsequently formed source/drain regions and inner spacers, and decrease the risk of shorting between the subsequently formed source/drain regions and gate structures as described in greater detail below. FIG. 7D illustrates a top-down view of a portion of the structures illustrated in FIGS. 7A, 7B, and 7C, including the second nanostructure 54A, along the reference cross-sections D-D′. FIG. 7E illustrates a top-down view of a portion of the structures illustrated in FIGS. 7A, 7B, and 7C, including the first nanostructure 52A, along the reference cross-sections E-E′.

In some embodiments, the portions of the dummy gate dielectrics 71 (e.g., the portions adjacent the exposed tilted sidewalls) may be removed by a doping process and an etching process. The exposed portions of the dummy gate dielectrics 71 may be doped by a suitable doping process, such as implantation doping or the like. In some embodiments, noble gas elements, such as argon, xenon, or the like, are used as dopants. In some embodiments, other inert dopants, such as nitrogen, fluorine, or the like, are used as the dopants. The doped portions of the dummy gate dielectrics 71 may be more easily removed than the undoped portions of the dummy gate dielectrics 71 in subsequent etching process. During the doping process, the STI regions 68A (circled in FIG. 7B by dotted lines) may also be doped. The STI regions 68A may be upper portions of the STI regions 68 adjacent the exposed top surfaces of the STI regions 68A. In some embodiments, the doped STI regions 68A are regions disposed directly underneath the exposed top surfaces of the STI regions 68 at a depth of less than 5 nm with a doping concentration smaller than 10¹⁹ cm⁻³. Said doping concentration may decrease as the depth from the exposed top surfaces of the STI regions 68 increase.

The doped portions of the dummy gate dielectrics 71 may be removed by a suitable etching process, such as wet etching or the like. The etching process may utilize an etchant which may selectively remove the doped portions of the dummy gate dielectrics 71 while leaving the second nanostructure 54A and the first nanostructure 52A as well as the undoped portions of the dummy gate dielectrics 71 substantially intact. In some embodiments, dilute hydrofluoric acid, such as one with a water to hydrofluoric acid ratio volume at 100:1, may be used as an etchant. In some embodiments, portions of the doped STI regions 68A are also removed by the etching process.

As shown in FIGS. 7D and 7E, after the etching process, dummy gate dielectrics 71 may have shapes of a rectangle in the top-down view. The dummy gate dielectrics 71 may have a width W5 at the interface between the dummy gate dielectrics 71 and the second nanostructure 54A and the width W2 at the interface between the dummy gate dielectrics 71 and the dummy gate 76 as illustrated in FIG. 7D. In some embodiments, the width W5 is equal to the width W2. Similarly after the etching process, the dummy gate dielectrics 71 may have shapes of a rectangle in the top-down view. The dummy gate dielectrics 71 may have a width W6 at an interface between the dummy gate dielectric 71 and the first nanostructure 52A, and the width W4 at the interface between the dummy gate dielectrics 71 and the dummy gate 76 as illustrated in FIG. 7E. In some embodiments, the width W6 is equal to the width W2.

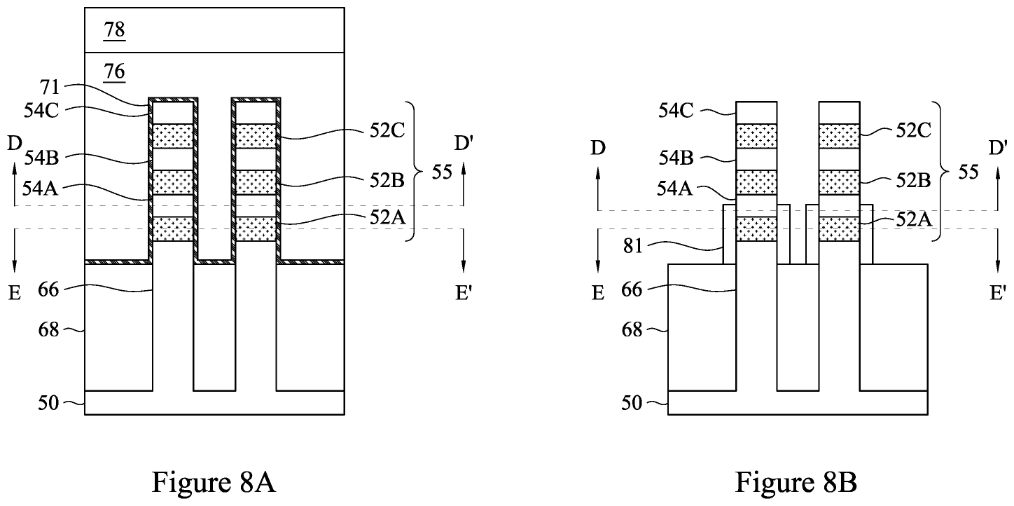

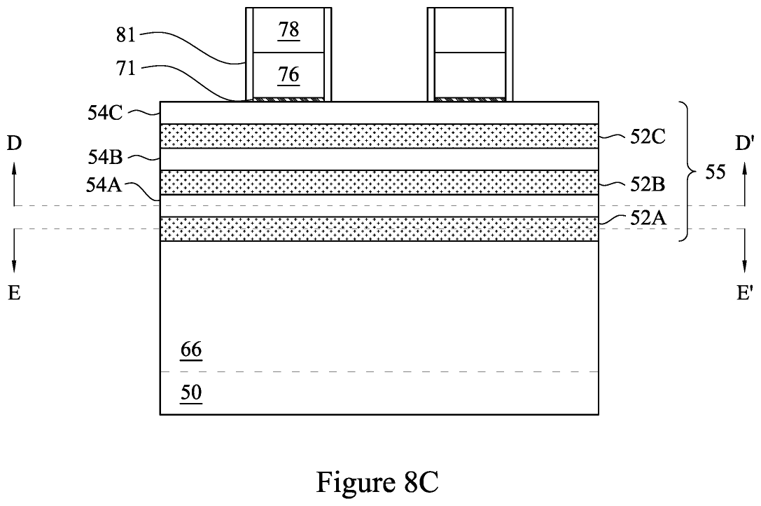

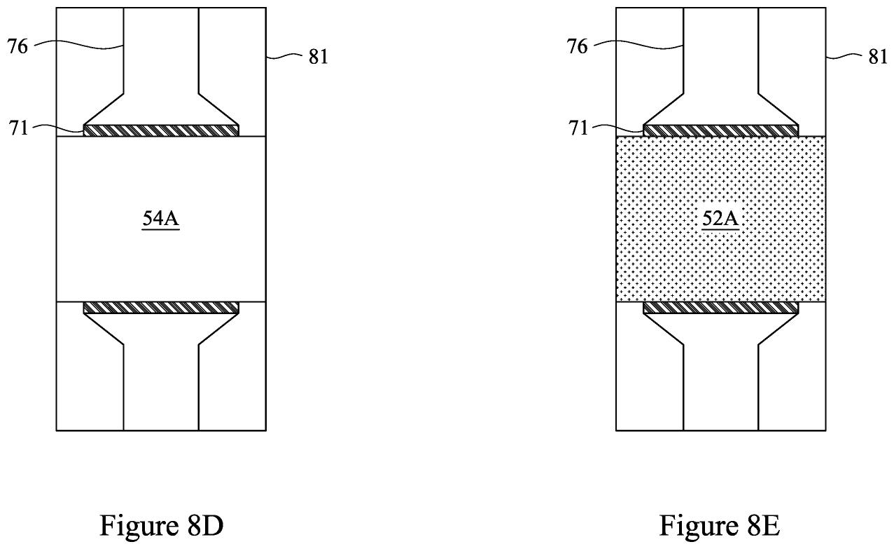

In FIGS. 8A through 8E, spacers 81 are formed. FIG. 8D illustrates a top-down view of a portion of the structures illustrated in FIGS. 8A, 8B, and 8C, including the second nanostructure 54A, along the reference cross-sections D-D′. FIG. 8E illustrates a top-down view of a portion of the structures illustrated in FIGS. 8A, 8B, and 8C, including the first nanostructure 52A, along the reference cross-sections E-E′. The spacers 81 may self-align subsequently formed source drain regions, as well as protect the dummy gate dielectrics 71 and the dummy gate 76 during subsequent etching processes. The spacers 81 may be a single layer of one material or multiple sub-layers of different materials with different etch rates. In some embodiments, the spacers 81 comprise two sub-layers with different materials of different etch rates, which may be selected from silicon oxide, silicon nitride, silicon oxynitride, or the like.

The spacers 81 may be formed by forming a spacer layer by thermal oxidation or a suitable deposition process, such as CVD, ΔLD, or the like, and then patterning the spacer layer by a suitable etching process, such as an isotropic etching process (e.g., a wet etching process), an anisotropic etching process (e.g., a dry etching process), or the like. The spacer layer may be formed on top surfaces of the STI regions 68; top surfaces and sidewalls of the fins 66, the nanostructures 55, and the masks 78; and sidewalls of the dummy gates 76 and the dummy gate dielectrics 71. After the etching process, the spacers 81 may remain on sidewalls of the fins 66 and/or nanostructures 55 as illustrated in FIG. 8B; and sidewalls of the masks 78, the dummy gates 76, and the dummy gate dielectrics 71 as illustrated in FIG. 8C.

In the embodiments in which the spacers 81 comprise two sublayers with different materials, after the first sublayer is formed and prior to forming the second sublayer, implants for lightly-doped source/drain (LDD) regions (not separately illustrated) may be performed. Similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly-doped source/drain regions may have a concentration of impurities in a range from about 1×10¹⁵ atoms/cm³ to about 1×10¹⁹ atoms/cm³. An annealing may be used to repair implant damage and to activate the implanted impurities.

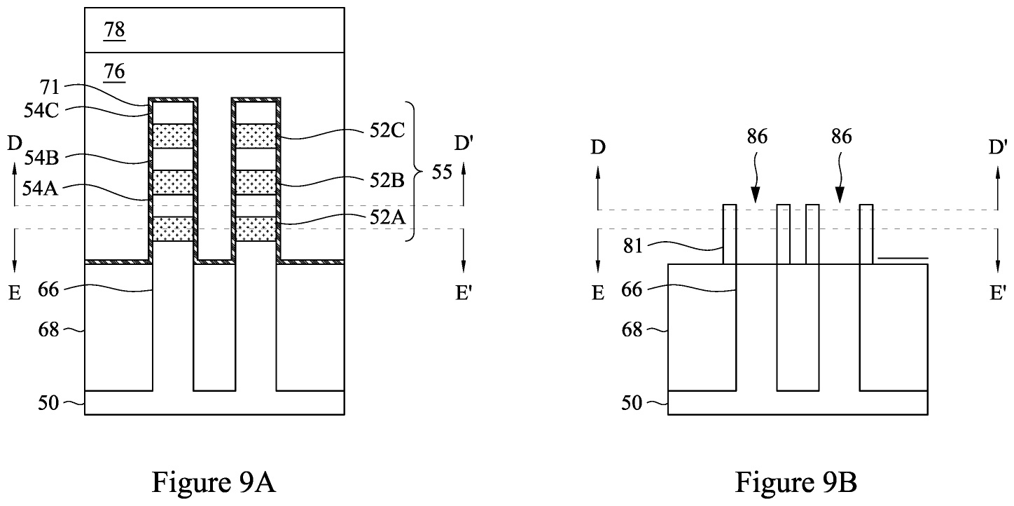

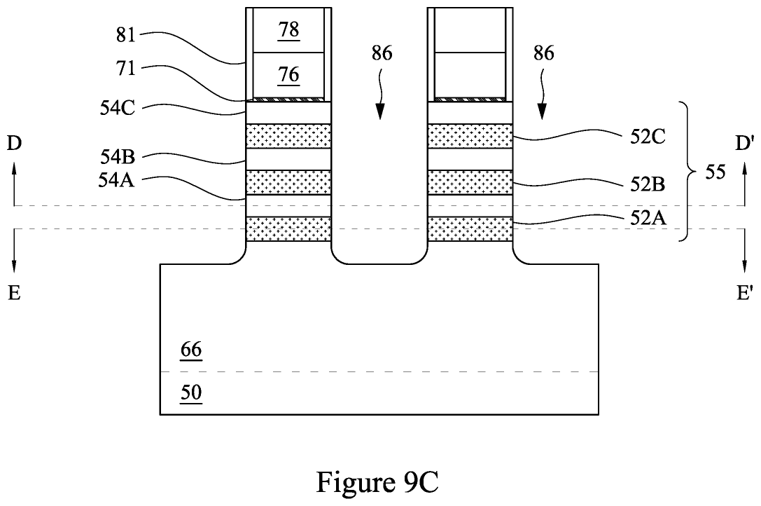

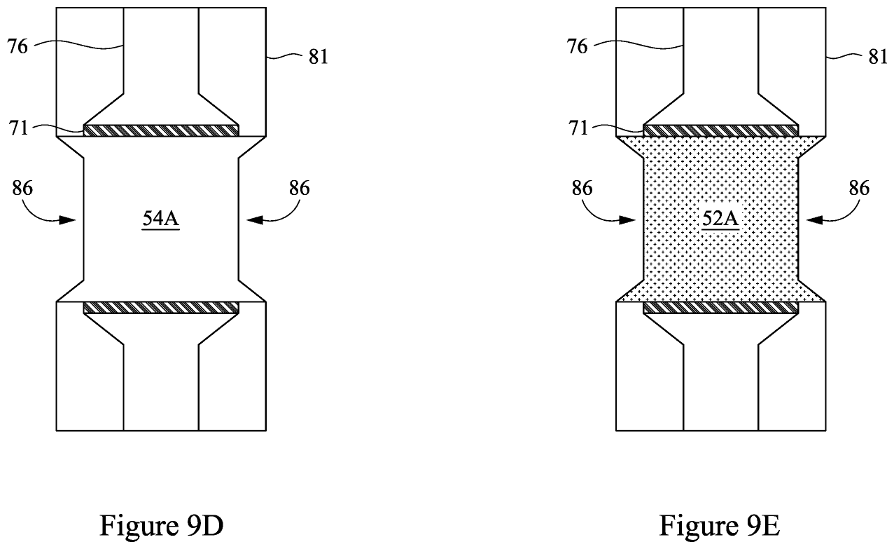

In FIGS. 9A through 9E, recesses 86 are formed in the fins 66, the nanostructures 55, and the substrate 50, in accordance with some embodiments. FIG. 9D illustrates a top-down view of a portion of the structures illustrated in FIGS. 9A, 9B, and 9C, including the second nanostructure 54A, along the reference cross-sections D-D′. FIG. 9E illustrates a top-down view of a portion of the structures illustrated in FIGS. 9A, 9B, and 9C, including the first nanostructure 52A, along the reference cross-sections E-E′. Epitaxial source/drain regions may be subsequently formed in the recesses 86. The recesses 86 may extend through the first nanostructures 52 and the second nanostructures 54, and into the substrate 50. As illustrated in FIG. 9B, top surfaces of the STI regions 68 may be level with bottom surfaces of the recesses 86. In some embodiments, the bottom surfaces of the recesses 86 are disposed below the top surfaces of the STI regions 68 or the like.

The recesses 86 may be formed by etching the fins 66, the nanostructures 55, and the substrate 50 using anisotropic etching processes, such as RIE, NBE, or the like. The spacers 81 and the masks 78 may mask portions of the fins 66, the nanostructures 55, and the substrate 50 during the etching processes used to form the recesses 86. A single etch process or multiple etch processes may be used to etch each layer of the nanostructures 55 and/or the fins 66. Timed etch processes may be used to stop the etching after the recesses 86 reach desired depths.

As illustrated in FIGS. 9D and 9E, the dummy gate dielectrics 71 remain un-exposed and covered by the spacers 81, the second nanostructure 54A, and the first nanostructure 52A after the etching processes. This may be due to the reduction of the widths of the dummy gate dielectrics 71 as previously described with respect to FIGS. 7A through 7E. As a result, the dummy gate dielectrics 71 are protected during the etching processes, which may improve the protection on subsequently formed source/drain regions and inner spacers, and decrease the risk of shorting between the subsequently formed source/drain regions and gate structures as described in greater detail below. The second nanostructure 54A and the first nanostructure 52A may have concave sidewalls in the top-down view after the recesses 86 are formed.

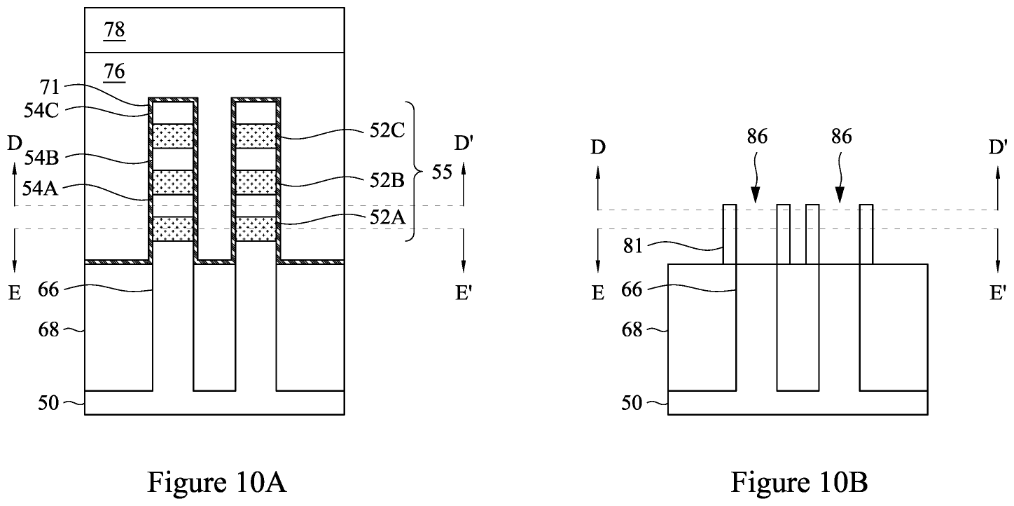

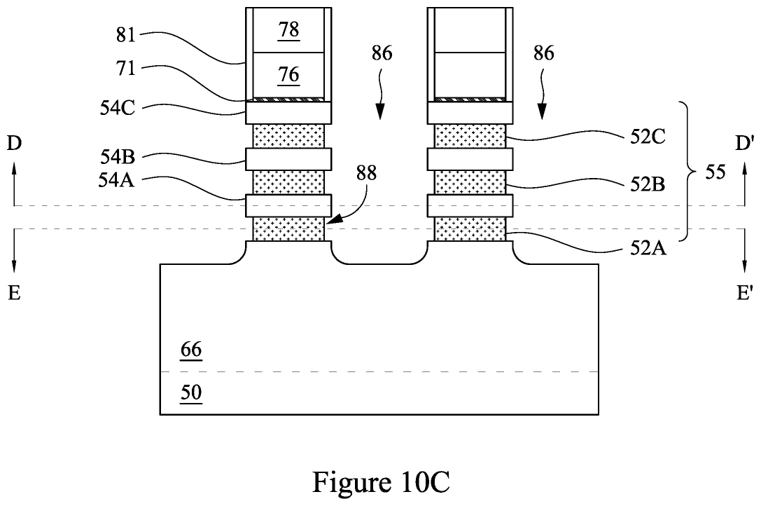

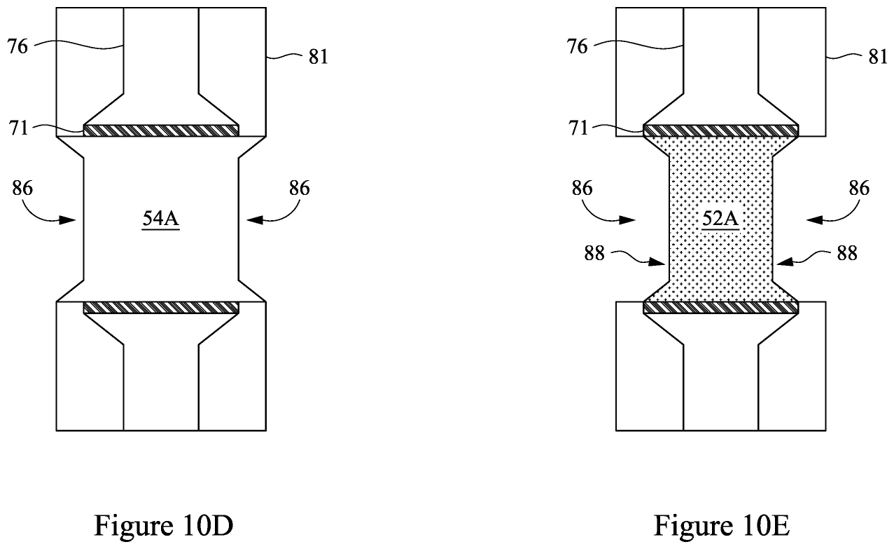

In FIGS. 10A through 10E, portions of sidewalls of the first nanostructures 52 exposed by the recesses 86 are etched to form sidewall recesses 88. FIG. 10D illustrates a top-down view of a portion of the structures illustrated in FIGS. 10A, 10B, and 10C, including the second nanostructure 54A, along the reference cross-sections D-D′. FIG. 10E illustrates a top-down view of a portion of the structures illustrated in FIGS. 10A, 10B, and 10C, including the first nanostructure 52A, along the reference cross-sections E-E′. Although sidewalls of the first nanostructures 52 adjacent the sidewall recesses 88 are illustrated as being straight in FIG. 10C, the sidewalls may be concave in some embodiments. The sidewalls may be etched using isotropic etching processes, such as wet etching or the like. In the embodiments in which the first nanostructures 52 comprise silicon-germanium or the like, and the second nanostructures 54 comprise silicon, silicon carbide, or the like, tetramethylammonium hydroxide (TMAH), ammonium hydroxide (NH₄OH), or the like may be used to etch sidewalls of the first nanostructures 52.

As illustrated in FIGS. 10D and 10E, the dummy gate dielectrics 71 remain un-exposed and covered by the spacers 81, the second nanostructure 54A, and the first nanostructure 52A after the etching processes. This may be due to the reduction of the widths of the dummy gate dielectrics 71 as previously described with respect to FIGS. 7A through 7E. As a result, the dummy gate dielectrics 71 are protected during the etching processes, which may improve the protection on subsequently formed source drain/regions and inner spacers and decrease the risk of shorting between the subsequently formed source/drain regions and gate structures as described in greater detail below.

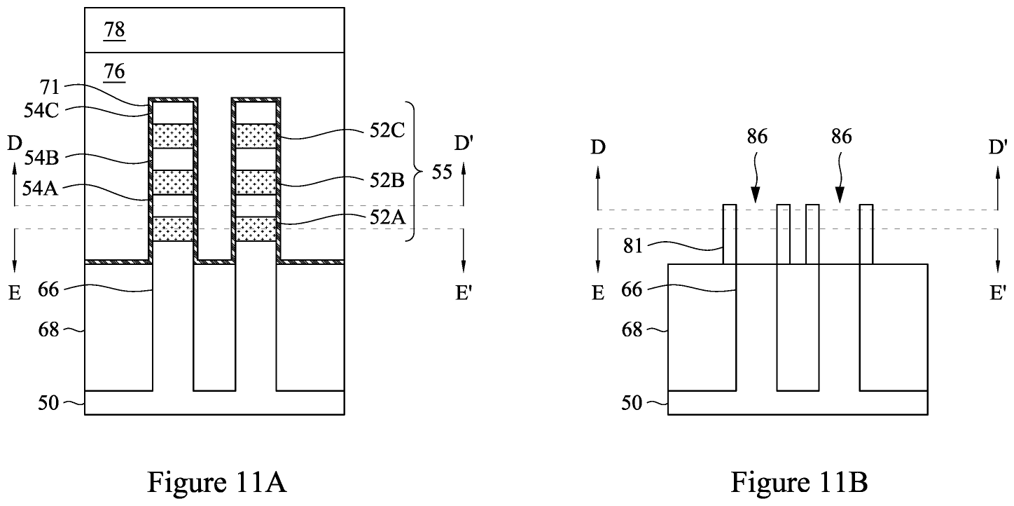

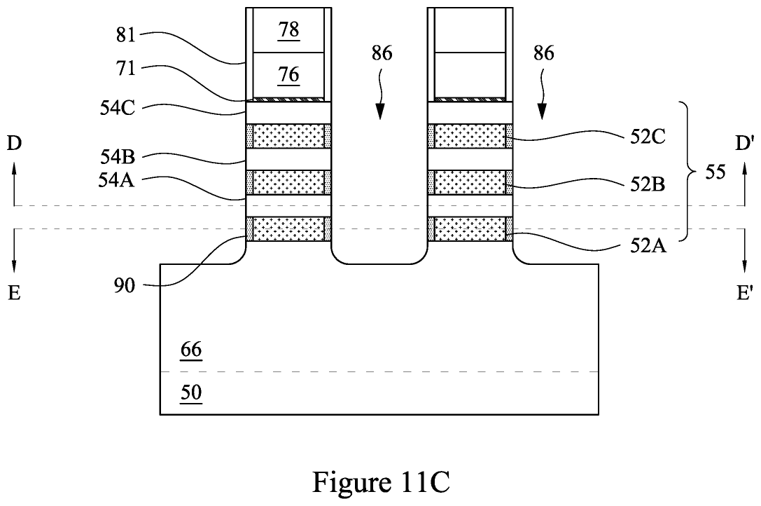

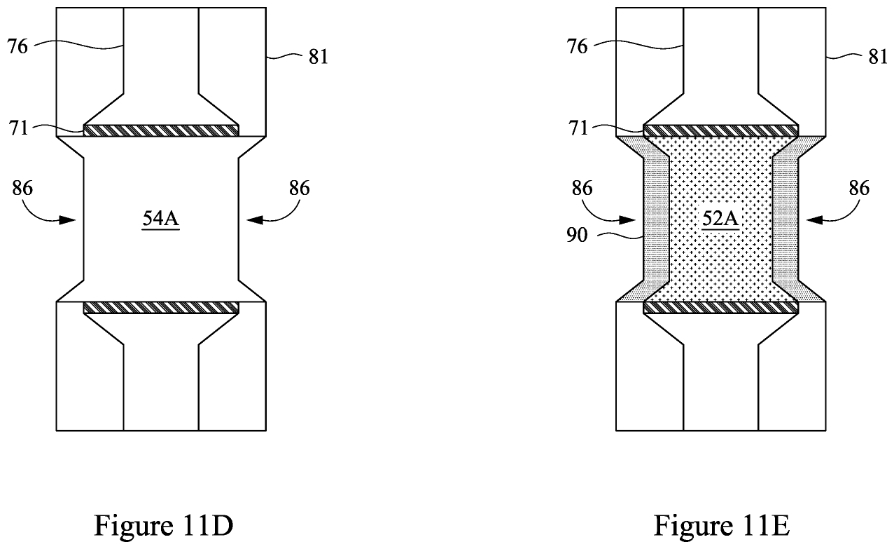

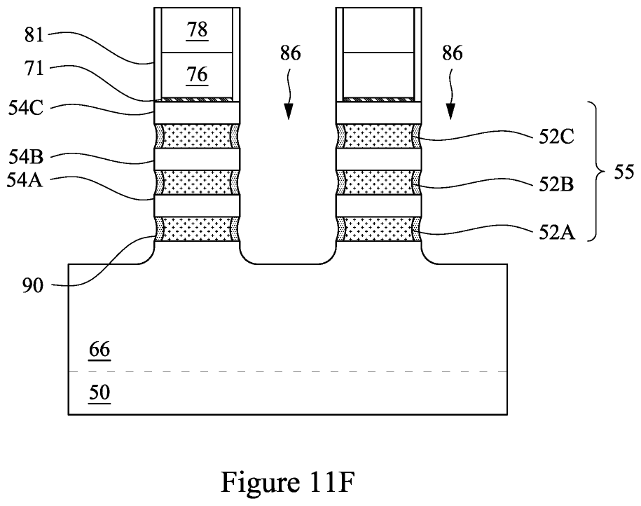

In FIGS. 11A through 11E, first inner spacers 90 are formed in the sidewall recess 88. FIG. 11D illustrates a top-down view of a portion of the structures illustrated in FIGS. 11A, 11B, and 11C, including the second nanostructure 54A, along the reference cross-sections D-D′. FIG. 11E illustrates a top-down view of a portion of the structures illustrated in FIGS. 11A, 11B, and 11C, including the first nanostructure 52A, along the reference cross-sections E-E′. The first inner spacers 90 may act as isolation features between subsequently formed source/drain regions and a gate structure. As will be discussed in greater detail below, source/drain regions may be formed in the recesses 86, while the first nanostructures 52 may be replaced with corresponding gate structures.

The first inner spacers 90 may be formed by depositing an inner spacer layer (not separately illustrated) over the structures illustrated in FIGS. 10A through 10C, and then etching the inner spacer layer. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be etched to form the first inner spacers 90 by an anisotropic etching process, such as RIE, NBE, or the like. The first inner spacers 90 may be used to protect subsequently formed source/drain regions during subsequent etching processes, such as etching processes used to form gate structures.

Although outer sidewalls of the first inner spacers 90 are illustrated as being flush with sidewalls of the second nanostructures 54, the outer sidewalls of the first inner spacers 90 may extend beyond or be recessed from sidewalls of the second nanostructures 54. Moreover, although the outer sidewalls of the first inner spacers 90 are illustrated as being straight in FIG. 11C, the outer sidewalls of the first inner spacers 90 may be concave. As an example, FIG. 11F illustrates the embodiments in which sidewalls of the first nanostructures 52 are concave, outer sidewalls of the first inner spacers 90 are concave, and the first inner spacers 90 are recessed from sidewalls of the second nanostructures 54.

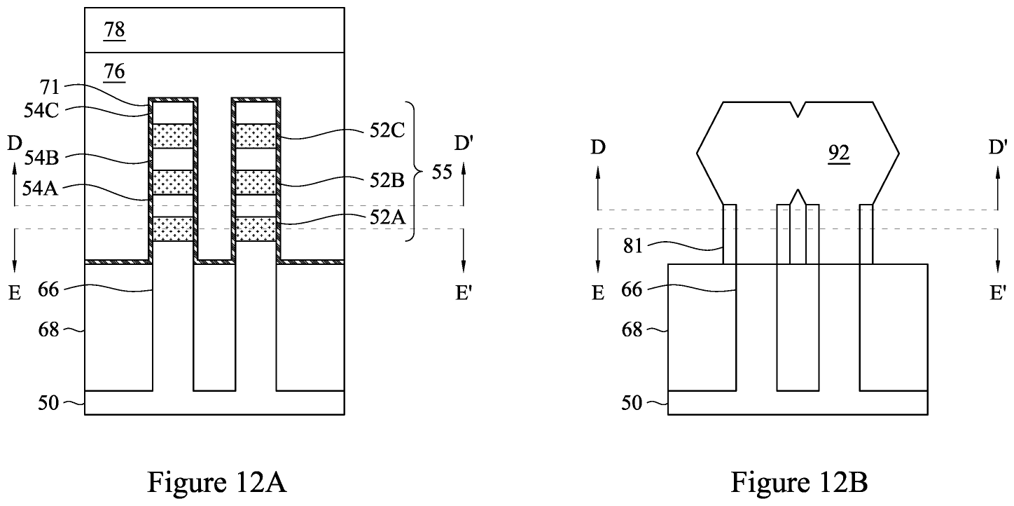

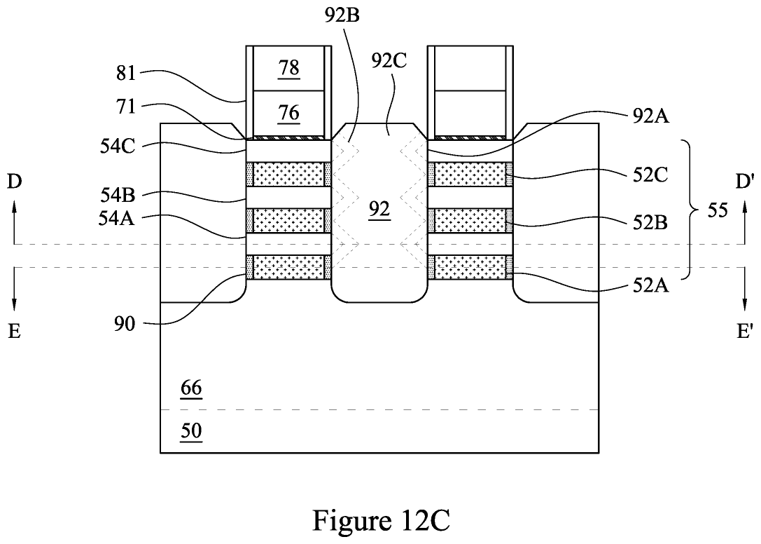

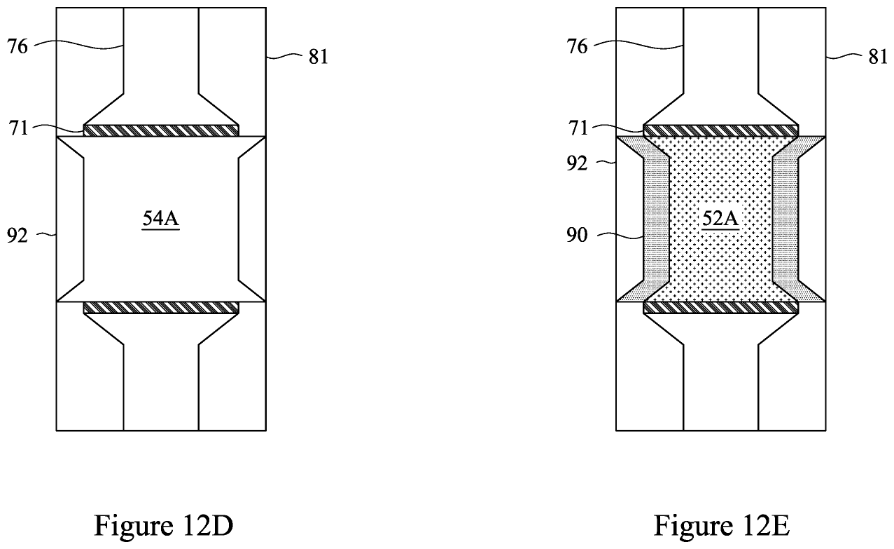

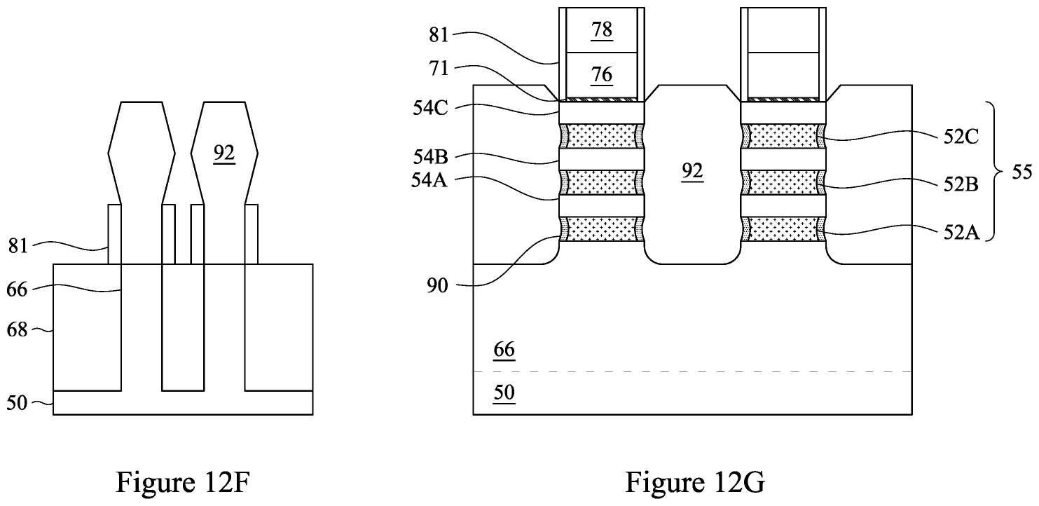

In FIGS. 12A through 12E, epitaxial source/drain regions 92 are formed in the recesses 86. FIG. 12D illustrates a top-down view of a portion of the structures illustrated in FIGS. 12A, 12B, and 12C, including the second nanostructure 54A, along the reference cross-sections D-D′. FIG. 12E illustrates a top-down view of a portion of the structures illustrated in FIGS. 12A, 12B, and 12C, including the first nanostructure 52A, along the reference cross-sections E-E′. In some embodiments, the epitaxial source/drain regions 92 may exert stress on the second nanostructures 54, thereby improving performance. As illustrated in FIG. 12C, the epitaxial source/drain regions 92 are formed in the recesses 86 such that each dummy gate 76 is disposed between respective neighboring pairs of the epitaxial source/drain regions 92.

As illustrated in FIG. 12D, the epitaxial source/drain regions 92 are separated from the dummy gate dielectrics 71 by the second nanostructures 54. As illustrated in FIG. 12E, the epitaxial source/drain regions 92 are separated from the dummy gate dielectrics 71 by the first nanostructure 52A and the first inner spacers 90. In some embodiments, the first inner spacers 90 are separated from the dummy gate dielectrics 71 by the first nanostructure 52A. This may be due to the reduction of the widths of the dummy gate dielectrics 71 as previously described with respect to FIGS. 7A through 7E. As a result, the epitaxial source/drain regions 92 and the first inner spacers 90 may be protected during subsequent etching processes and the risk of shorting between the epitaxial source/drain regions 92 and the subsequently formed gate structures may be decreased as described in greater detail below.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the recesses 86 in the p-type region 50P. The epitaxial source/drain regions 92 may include any acceptable material appropriate for p-type nano-FETs. For example, if the first nanostructures 52 are silicon germanium, the epitaxial source/drain regions 92 may comprise materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the multi-layer stack 64 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 12B. In some embodiments, adjacent epitaxial source/drain regions 92 remain separated after the epitaxy process is completed as illustrated by FIG. 12F. In the embodiments illustrated in FIGS. 12B and 12F, the spacers 81 may be formed to a top surface of the STI regions 68 thereby blocking the epitaxial growth. In some embodiments, the etching process used to form the spacers 81 may be adjusted to remove the spacer material to allow the epitaxially grown region to extend to the surface of the STI region 58.

The epitaxial source/drain regions 92 may comprise one or more semiconductor material layers. In some embodiments, the epitaxial source/drain regions 92 comprise first liner layers 92A on the sidewalls of the second nanostructures 54, second liner layers 92B on the first liner layers 92A, and fill layers 92C on the second liner layers 92B, as shown in FIG. 12C. The first liner layers 92A, the second liner layers 92B, and the fill layers 92C may be formed of different semiconductor materials and/or may be doped to different dopant concentrations. The first liner layers 92A may be grown first, the second liner layers 92B may be grown on the first liner layers 92A, and the fill layers 92C may be grown on the second liner layers 92B.

FIG. 12G illustrates the embodiments in which sidewalls of the first nanostructures 52 are concave, outer sidewalls of the first inner spacers 90 are concave, and the first inner spacers 90 are recessed from sidewalls of the second nanostructures 54. As illustrated in FIG. 12E, the epitaxial source/drain regions 92 may be formed in contact with the first inner spacers 90 and may extend past sidewalls of the second nanostructures 54.

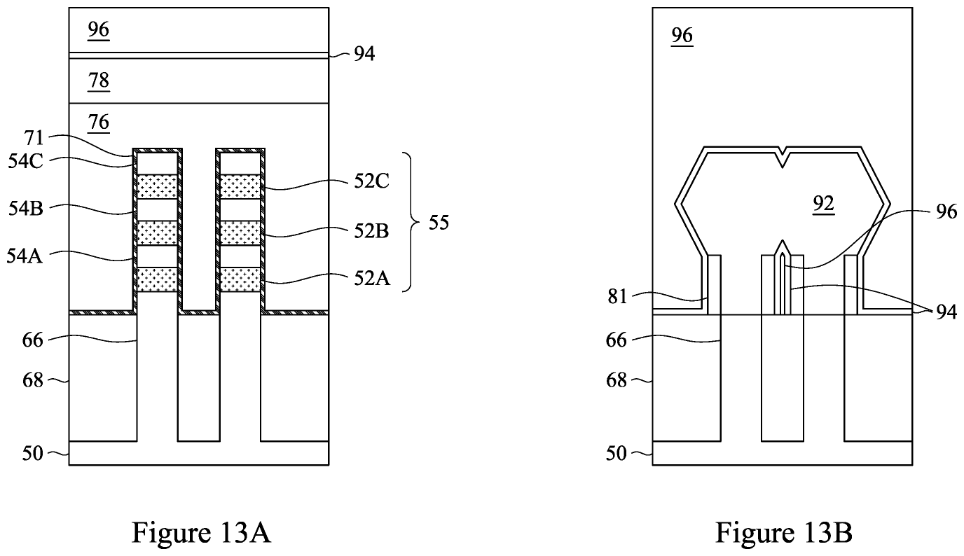

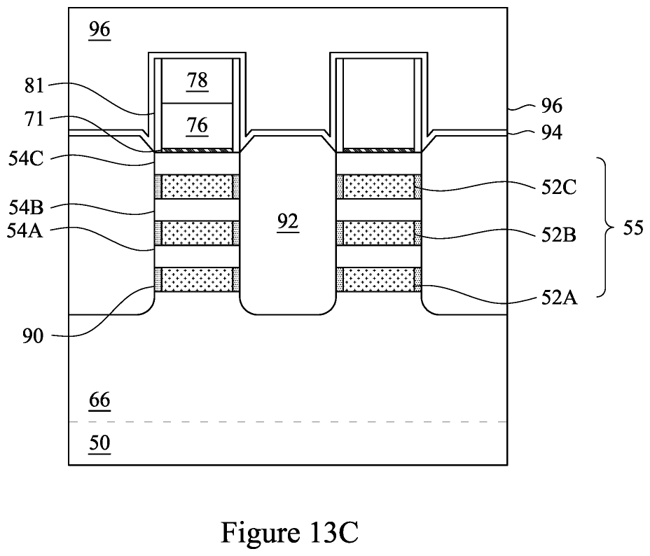

In FIGS. 13A through 13C, a first interlayer dielectric (ILD) 96 is deposited over the structure illustrated in FIGS. 12A through 12C. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the spacers 81. The CESL 94 may comprise a dielectric material, such as, silicon nitride, silicon oxide, silicon oxynitride, or the like, having a different etch rate than the material of the overlying first ILD 96.

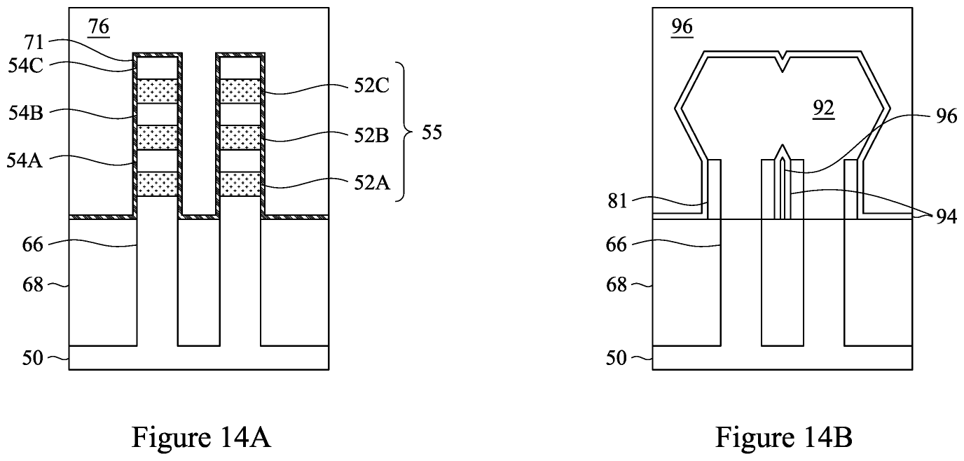

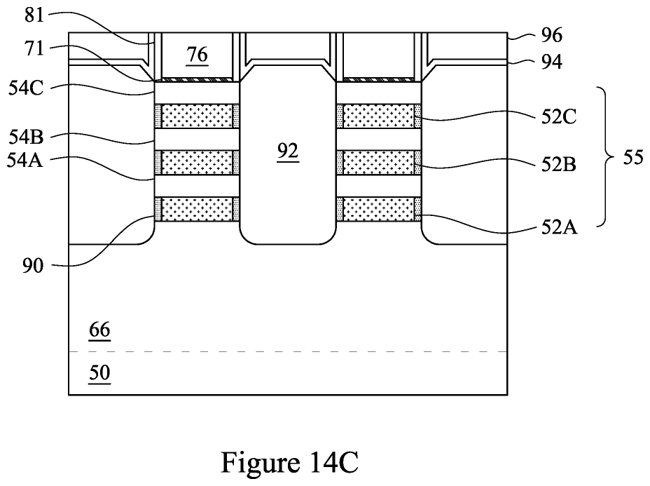

In FIGS. 14A through 14C, a planarization process, such as CMP, may be performed to level the top surface of the first ILD 96 with the top surfaces of the dummy gates 76 or the masks 78. The planarization process may also remove the masks 78 on the dummy gates 76, and portions of the spacers 81 along sidewalls of the masks 78. After the planarization process, top surfaces of the dummy gates 76, the spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the spacers 81.

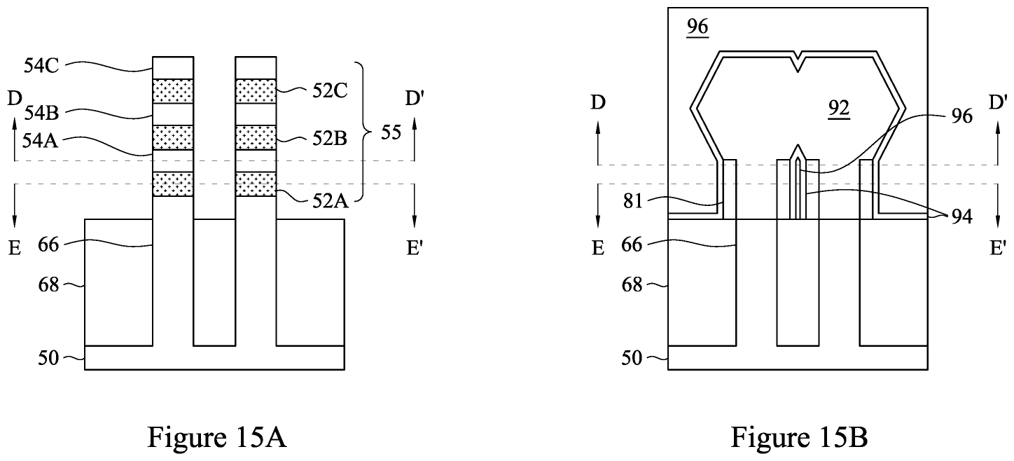

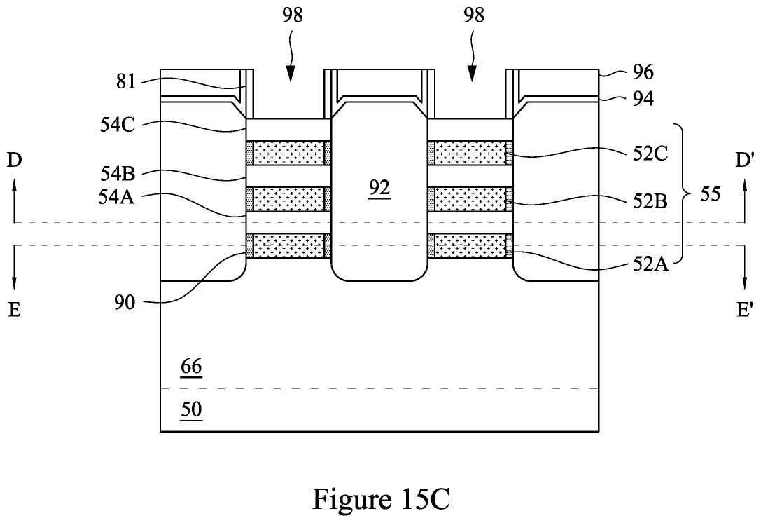

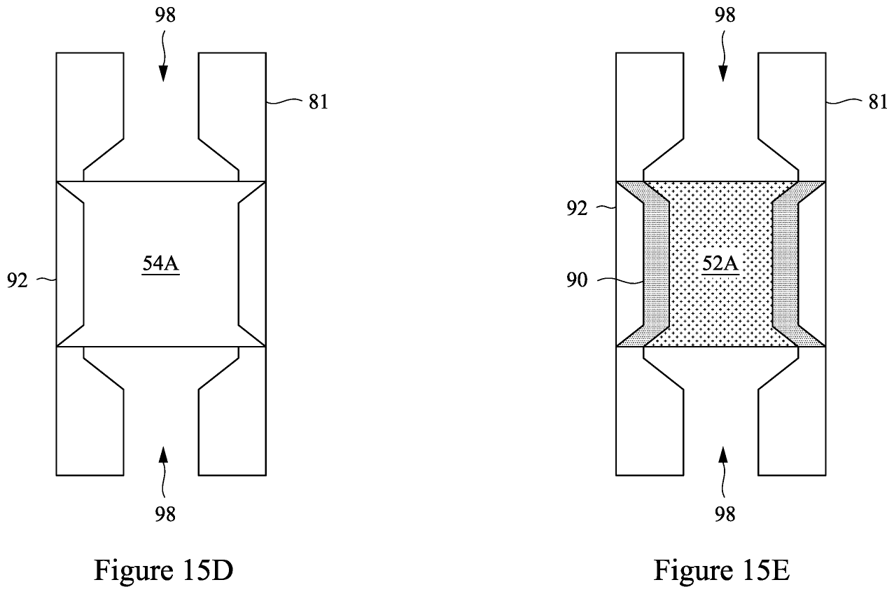

In FIGS. 15A through 15E, the dummy gates 76 and the dummy gate dielectrics 71 are removed in one or more etching processes to form third recesses 98. FIG. 15D illustrates a top-down view of a portion of the structures illustrated in FIGS. 15A, 15B, and 15C, including the second nanostructure 54A, along the reference cross-sections D-D′. FIG. 15E illustrates a top-down view of a portion of the structures illustrated in FIGS. 15A, 15B, and 15C, including the first nanostructure 52A, along the reference cross-sections E-E′. In some embodiments, the dummy gates 76 and the dummy gate dielectrics 71 are removed by an anisotropic dry etch process. For example, the etching processes may include dry etching processes using reaction gas(es) that selectively etch the dummy gates 76 and the dummy gate dielectrics 71 at faster rates than the first ILD 96 and/or the spacers 81. Each of the third recess 98 exposes and/or overlies portions of nanostructures 55, which act as channel regions in subsequently completed nano-FETs. Portions of the nanostructures 55, which may act as the channel regions, are disposed between neighboring pairs of the epitaxial source/drain regions 92.

During the etching processes, the dummy gate dielectrics 71 may be used as etch stop layers when the dummy gates 76 are removed and may be removed after the removal of the dummy gates 76. Due to the separation of the epitaxial source/drain regions 92 from the dummy gate dielectrics 71 and the separation of the epitaxial source/drain regions 92 and the first inner spacers 90 from the dummy gate dielectrics 71 as described with respect to FIGS. 12A through 12E, the source/drain regions 92 and the first inner spacers 90 may be protected during the etching processes and the risk of shorting between the epitaxial source/drain regions 92 and the subsequently formed gate structures may be decreased as described in greater detail below.

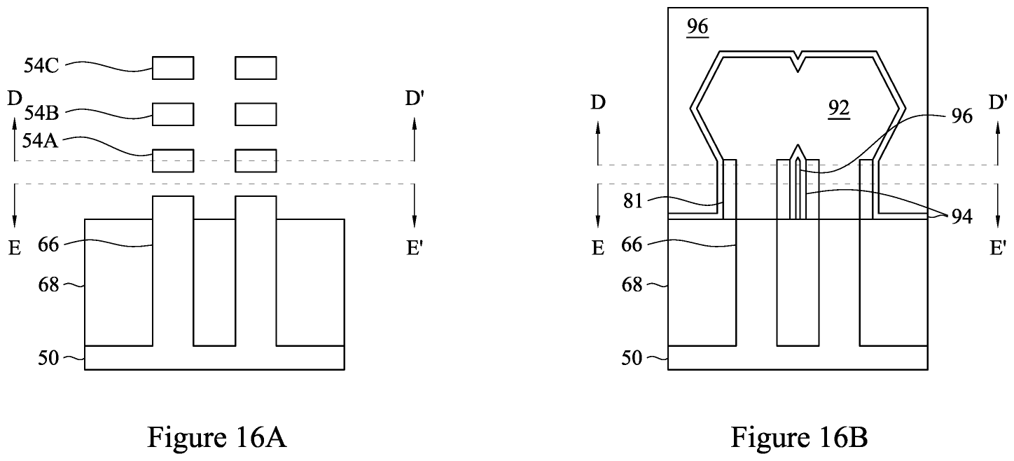

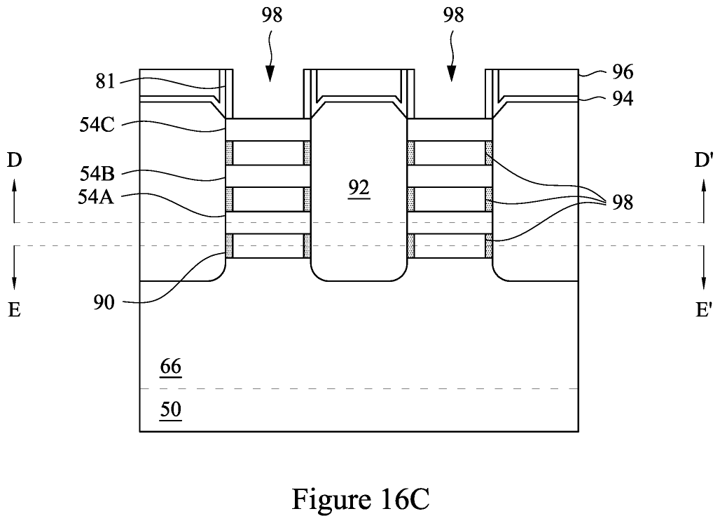

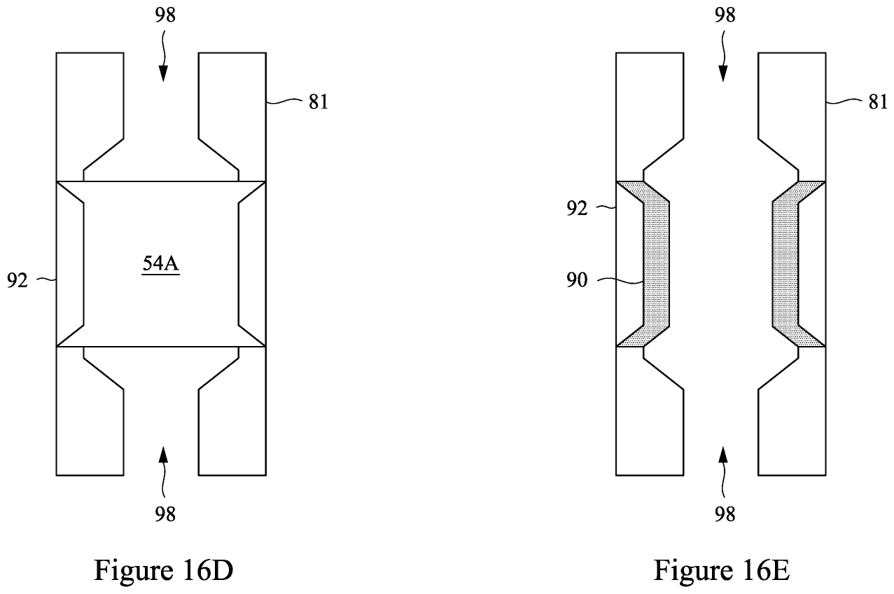

In FIGS. 16A through 16E, the first nanostructures 52 are removed, which extends the third recesses 98. FIG. 16D illustrates a top-down view of a portion of the structures illustrated in FIGS. 16A, 16B, and 16C, including the second nanostructure 54A, along the reference cross-sections D-D′. FIG. 16E illustrates a top-down view of a portion of the structures illustrated in FIGS. 16A, 16B, and 16C along the reference cross-sections E-E′. The first nanostructures 52 may be removed by performing an isotropic etching process such as wet etching or the like using etchants which are selective to the materials of the first nanostructures 52, while the second nanostructures 54, the substrate 50, the STI regions 68 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52.

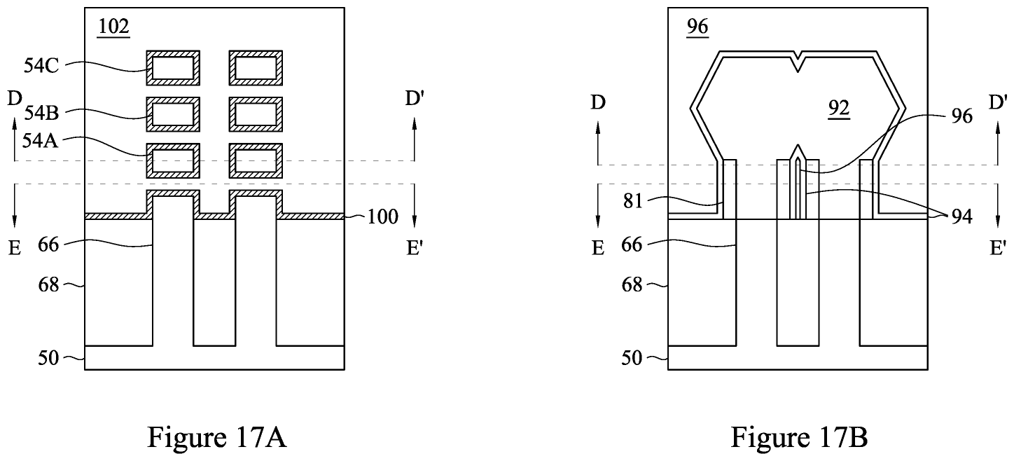

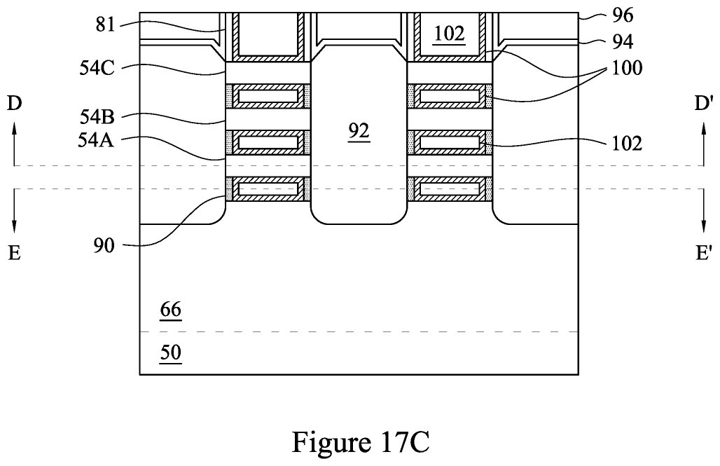

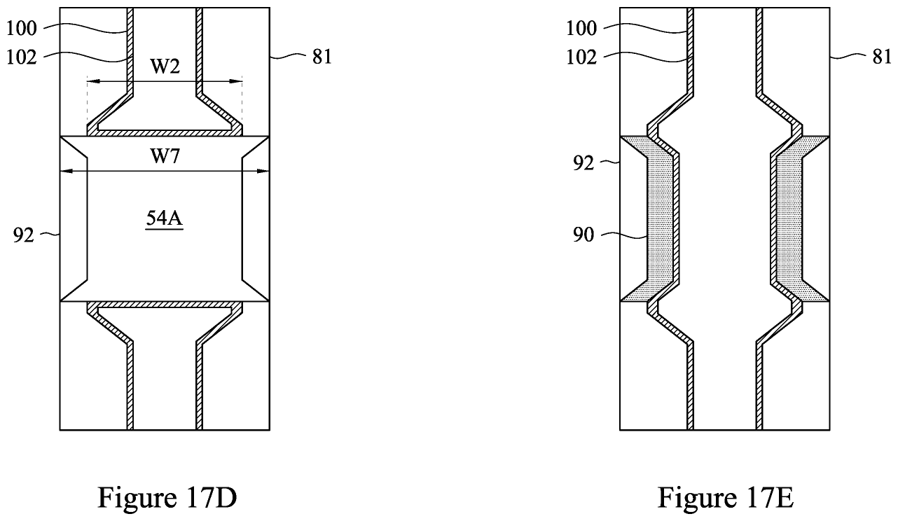

In FIGS. 17A through 17E, gate dielectric layers 100 and gate electrodes 102 are formed in the third recesses 98. FIG. 17D illustrates a top-down view of a portion of the structures illustrated in FIGS. 17A, 17B, and 17C, including the second nanostructure 54A, along the reference cross-sections D-D′. FIG. 17E illustrates a top-down view of a portion of the structures illustrated in FIGS. 17A, 17B, and 17C along the reference cross-sections E-E′. The gate dielectric layers 100 may be deposited conformally in the third recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the spacers 81, and the STI regions 68 as well as on sidewalls of the spacers 81 and the first inner spacers 90.

In some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a dielectric constant (k) value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, or the like.

The gate electrodes 102 are deposited over the gate dielectric layers 100, respectively, and fill the remaining portions of the third recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A, 17C, 17D, and 17E, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the third recesses 98, a planarization process, such as CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as gate structures.

The gate structures may be separated from the epitaxial source/drain regions 92. As shown in FIG. 17D, the second nanostructure 54A may have a width W7 at an interface between the gate structure and the second nanostructure 54A, and the gate structure may have the width W2 at the interface between the gate structure and the second nanostructure 54A. In some embodiments, the width W7 is larger than the width W2. This may be due to the reduction of the widths of the dummy gate dielectrics 71 as previously described with respect to FIGS. 7A through 7E. As a result, the risk of shorting between the epitaxial source/drain regions 92 and the gate structures may be decreased, thereby improving the performance and reliability of the subsequently formed semiconductor device. Portions of the gate structures in contact with the second nanostructure 54A may have shapes of a trapezoid. Widths of the portions of the gate structures may decrease as the gate structure extends away from the second nanostructure 54A.

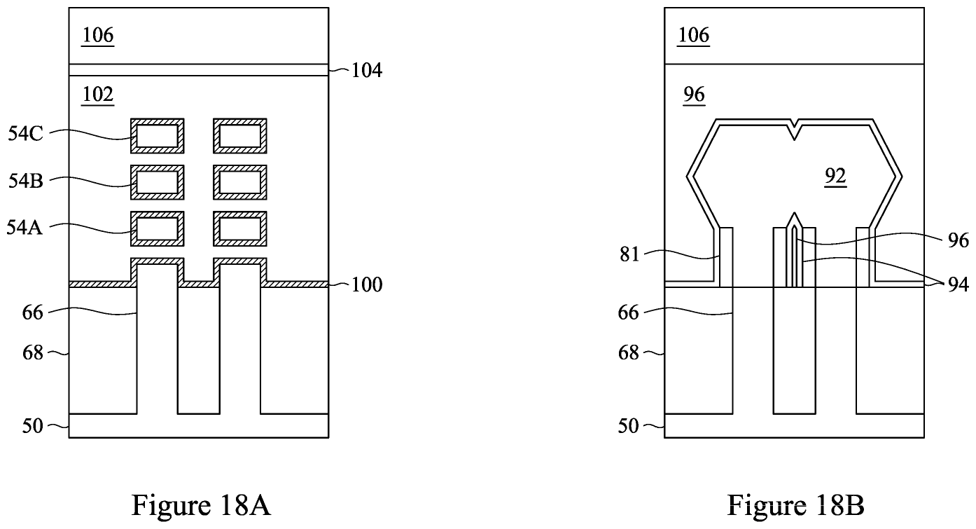

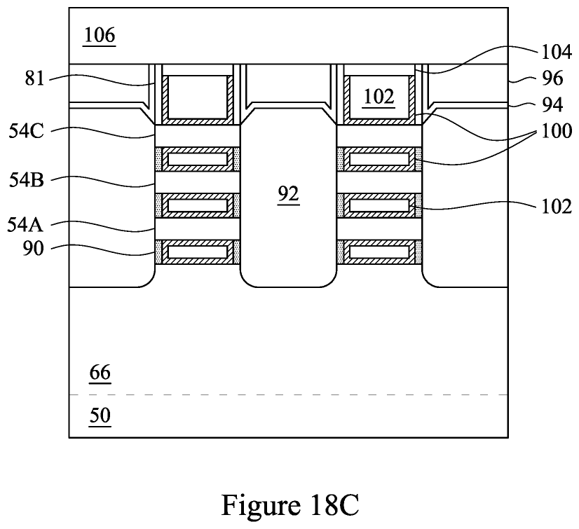

In FIGS. 18A through 18C, the gate structures (including the gate dielectric layers 100 and the corresponding overlying gate electrodes 102) are recessed, and recesses are formed directly over the gate structures and between opposing portions of spacers 81. Gate masks 104 comprising one or more layers of dielectric material, such as silicon nitride, silicon oxynitride, or the like, are filled in the recesses, followed by a planarization process to remove excess portions of the dielectric material extending over the first ILD 96. Subsequently formed gate contacts may extend through the gate masks 104 to contact the top surfaces of the recessed gate electrodes 102. As further illustrated by FIGS. 18A through 18C, a second ILD 106 is deposited over the first ILD 96 and over the gate masks 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

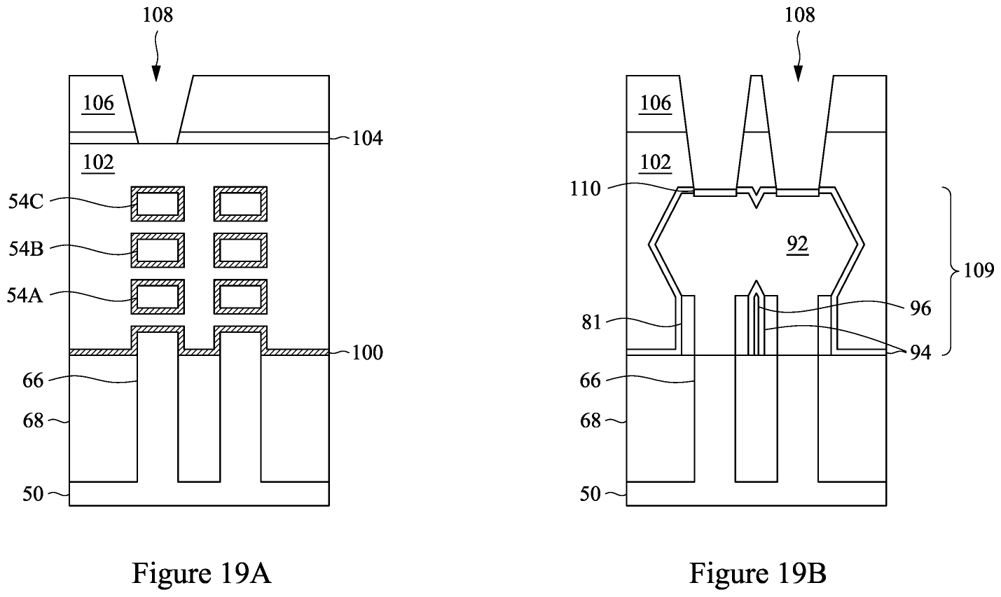

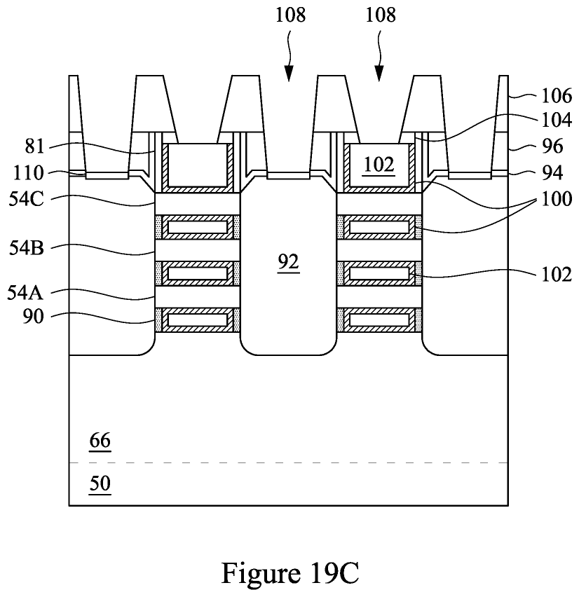

In FIGS. 19A through 19C, the second ILD 106, the first ILD 96, the CESL 94, and the gate masks 104 are etched to form fourth recesses 108 exposing surfaces of the epitaxial source/drain regions 92 and/or some of the gate structures. The fourth recesses 108 may be formed by etching using an anisotropic etching process, such as RIE, NBE, or the like. In some embodiments, the fourth recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the fourth recesses 108 extend into the epitaxial source/drain regions 92 and/or some of the gate structures, and a bottom of the fourth recesses 108 may be level with (e.g., at a same level, or having a same distance from the substrate 50), or lower than (e.g., closer to the substrate 50) the epitaxial source/drain regions 92 and/or some of the gate structures.

After the fourth recesses 108 are formed, first silicide regions 110 are formed over the epitaxial source/drain regions 92. In some embodiments, the first silicide regions 110 are formed by first depositing a metal (not separately illustrated) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a first thermal annealing process to form the first silicide regions 110. In some embodiments, the first thermal annealing process is performed at a temperate of about 450° C. The un-reacted portions of the deposited metal are then removed, e.g., by an etching process. Although the first silicide regions 110 are referred to as silicide regions, the first silicide regions 110 may also be germanide regions, or silicon germanide regions (e.g., regions comprising silicide and germanide).

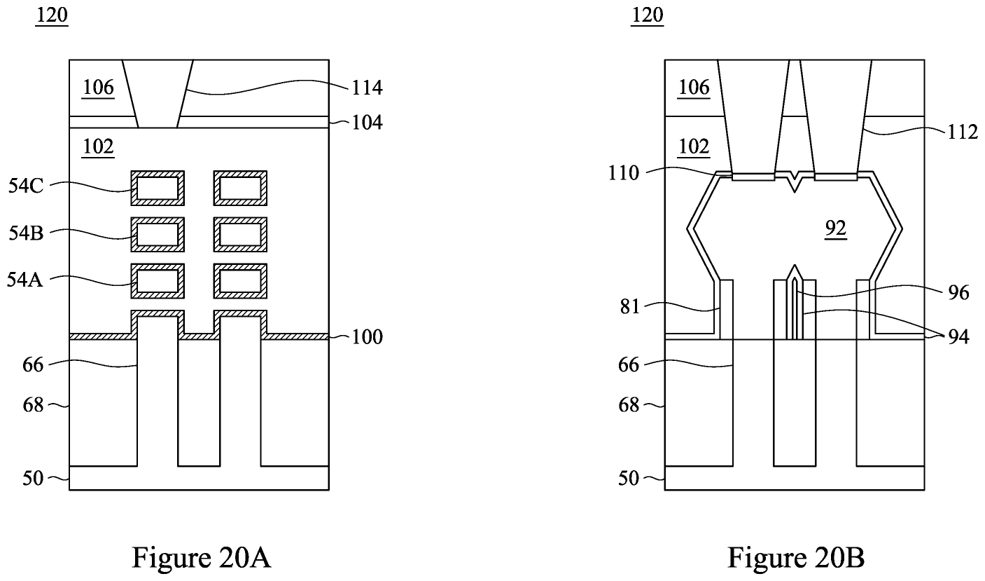

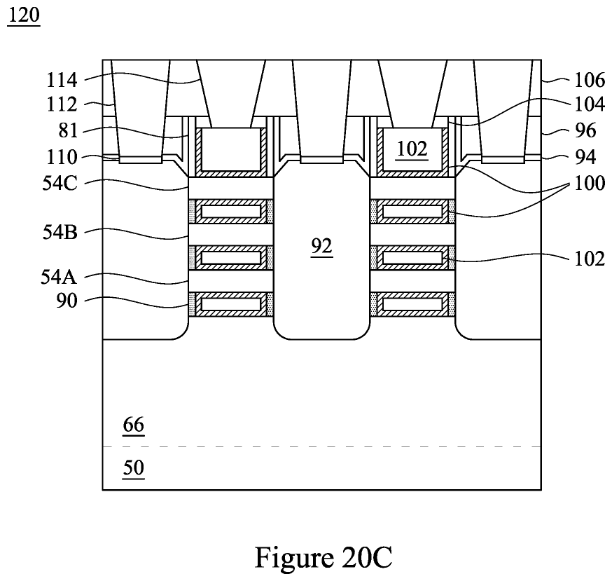

In FIGS. 20A through 20C, source/drain contacts 112 and gate contacts 114, which may be also referred to as conductive contacts, are formed in the fourth recesses 108. The source/drain contacts 112 and the gate contacts 114 may each comprise one or more layers, such as barrier layers, diffusion layers, and fill materials. For example, in some embodiments, the source/drain contacts 112 and the gate contacts 114 each include a barrier layer and a conductive material, and are each electrically connected to an underlying conductive feature (e.g., a gate electrode 102 and/or a first silicide region 110). The gate contacts 114 are electrically connected to the gate electrodes 102 and the source/drain contacts 112 are electrically connected to the first silicide regions 110. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as CMP, may be performed to remove excess material from surfaces of the second ILD 106. The structure shown in FIGS. 20A through 20C may be referred to as semiconductor device 120.

The embodiments of the present disclosure have some advantageous features. By reducing the widths of the dummy gate dielectrics 71, the risk of damaging the dummy gate dielectrics 71 by subsequent etching processes may be decreased, the protection on the epitaxial source/drain regions 92 and the first inner spacers 90 may be improved, and the risk of shorting between the epitaxial source/drain regions 92 and gate structures may be decreased. As a result, the performance and reliability of the semiconductor device 120 may be improved.

In an embodiment, a semiconductor device includes a substrate; a fin structure protruding from the substrate; an isolation region on the substrate and along a sidewall of the fin structure, wherein an upper portion of the isolation region includes first dopants of a first noble gas element; a stack of nanostructures over the fin structure, wherein the stack of nanostructures includes a first nanostructure; a gate structure extending between nanostructures of the stack of nanostructures and around the first nanostructure; and a first source/drain region and a second source/drain region, wherein the stack of nanostructures are between the first source/drain region and the second source/drain region. In an embodiment, the first dopants are disposed at a depth less than 5 nm from a top surface of the isolation region. In an embodiment, the first dopants have a first concentration in the isolation region, wherein the first concentration is smaller than 10¹⁹ cm⁻³. In an embodiment, the first noble gas element is argon. In an embodiment, the first noble gas element is xenon. In an embodiment, a width of the gate structure decreases as the gate structure extends away from a sidewall of the first nanostructure in a top-down view. In an embodiment, a width of the first nanostructure is larger than a width of the gate structure adjacent a sidewall of the first nanostructure.

In an embodiment, a method of forming a semiconductor device includes forming a stack of nanostructures over a fin, wherein the stack of nanostructures includes a first nanostructure; forming a dummy gate structure over the stack of nanostructures, the dummy gate structure including a dummy gate dielectric layer on a top surface and sidewalls of the stack of nanostructures and a dummy gate layer over the dummy gate dielectric layer, wherein the dummy gate dielectric layer has a first width at an interface between the dummy gate dielectric layer and a first sidewall of the first nanostructure in a top-down view; doping exposed portions of the dummy gate dielectric layer with first dopants; and etching the exposed portions of the dummy gate dielectric layer, wherein after etching the exposed portions of the dummy gate dielectric layer, the dummy gate dielectric layer has a second width at the interface between the dummy gate dielectric layer and the first sidewall of the first nanostructure in the top-down view, and wherein the second width is smaller than the first width. In an embodiment, the first dopants include argon or xenon. In an embodiment, the first dopants include nitrogen or fluorine. In an embodiment, the first nanostructure is in contact with the fin. In an embodiment, etching the exposed portions of the dummy gate dielectric layer includes using dilute hydrofluoric acid. In an embodiment, the method further includes forming an isolation region along sidewalls of the fin and doping the isolation region with the first dopants while doping the exposed portions of the dummy gate dielectric layer with the first dopants, wherein the first dopants are disposed at a depth less than 5 nm from a top surface of the isolation region. In an embodiment, the first dopants have a first concentration in a first region of the isolation region, and wherein the first concentration is smaller than 10¹⁹ cm⁻³. In an embodiment, the first dopants have a second concentration in a second region of the isolation region, wherein the second region is further from a top surface of the isolation region than the first region, and wherein the second concentration is smaller than the first concentration.

In an embodiment, a method of forming a semiconductor device includes forming a stack of nanostructures on a fin, wherein the stack of nanostructures includes a first nanostructure over the fin and a second nanostructure over the first nanostructure; forming an isolation region along sidewalls of the fin; forming a dummy gate structure including a first dummy gate layer on a top surface and sidewalls of the stack of nanostructures and a second dummy gate layer on the first dummy gate layer, wherein the first dummy gate layer is on a first sidewall of the first nanostructure and a first sidewall of the second nanostructure; doping exposed portions of the first dummy gate layer with first dopants; and etching the exposed portions of the first dummy gate, wherein after etching the exposed portions of the first dummy gate layer, a width of the first dummy gate layer at an interface between the first dummy gate layer and the first sidewall of the first nanostructure in a top-down view is reduced, and a width of the first dummy gate layer at an interface between the first dummy gate layer and the first sidewall of the second nanostructure in the top-down view is reduced. In an embodiment, the first dopants include a noble gas element. In an embodiment, the method further includes doping the isolation region with the first dopants while doping the exposed portions of the first dummy gate layer with the first dopants. In an embodiment, the first dopants are disposed at a depth less than 5 nm from a top surface of the isolation region. In an embodiment, the first nanostructure includes a first semiconductor material and the second nanostructure includes a second semiconductor material different from the first semiconductor material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate;
a fin structure protruding from the substrate;
an isolation region on the substrate and along a sidewall of the fin structure, wherein an upper portion of the isolation region comprises first dopants of a first noble gas element;
a stack of nanostructures over the fin structure, wherein the stack of nanostructures comprises a first nanostructure;
a gate structure extending between nanostructures of the stack of nanostructures and around the first nanostructure; and
a first source/drain region and a second source/drain region, wherein the stack of nanostructures are between the first source/drain region and the second source/drain region.

2. The semiconductor device of claim 1, wherein the first dopants are disposed at a depth less than 5 nm from a top surface of the isolation region.

3. The semiconductor device of claim 1, wherein the first dopants have a first concentration in the isolation region, wherein the first concentration is smaller than 10¹⁹ cm⁻³.

4. The semiconductor device of claim 1, wherein the first noble gas element is argon.

5. The semiconductor device of claim 1, wherein the first noble gas element is xenon.

6. The semiconductor device of claim 1, wherein a width of the gate structure decreases as the gate structure extends away from a sidewall of the first nanostructure in a top-down view.

7. The semiconductor device of claim 1, wherein a width of the first nanostructure is larger than a width of the gate structure adjacent a sidewall of the first nanostructure.

8. A method of forming a semiconductor device, the method comprising:
forming a stack of nanostructures over a fin, wherein the stack of nanostructures comprises a first nanostructure;
forming a dummy gate structure over the stack of nanostructures, the dummy gate structure comprising a dummy gate dielectric layer on a top surface and sidewalls of the stack of nanostructures and a dummy gate layer over the dummy gate dielectric layer, wherein the dummy gate dielectric layer has a first width at an interface between the dummy gate dielectric layer and a first sidewall of the first nanostructure in a top-down view;
doping exposed portions of the dummy gate dielectric layer with first dopants; and
etching the exposed portions of the dummy gate dielectric layer, wherein after etching the exposed portions of the dummy gate dielectric layer, the dummy gate dielectric layer has a second width at the interface between the dummy gate dielectric layer and the first sidewall of the first nanostructure in the top-down view, and wherein the second width is smaller than the first width.

9. The method of claim 8, wherein the first dopants comprise argon or xenon.

10. The method of claim 8, wherein the first dopants comprise nitrogen or fluorine.

11. The method of claim 8, wherein the first nanostructure is in contact with the fin.

12. The method of claim 8, wherein etching the exposed portions of the dummy gate dielectric layer comprises using dilute hydrofluoric acid.

13. The method of claim 8, further comprising forming an isolation region along sidewalls of the fin and doping the isolation region with the first dopants while doping the exposed portions of the dummy gate dielectric layer with the first dopants, wherein the first dopants are disposed at a depth less than 5 nm from a top surface of the isolation region.

14. The method of claim 13, wherein the first dopants have a first concentration in a first region of the isolation region, and wherein the first concentration is smaller than 10¹⁹ cm⁻³.

15. The method of claim 14, wherein the first dopants have a second concentration in a second region of the isolation region, wherein the second region is further from a top surface of the isolation region than the first region, and wherein the second concentration is smaller than the first concentration.

16. A method of forming a semiconductor device, the method comprising:
forming a stack of nanostructures on a fin, wherein the stack of nanostructures comprises a first nanostructure over the fin and a second nanostructure over the first nanostructure;
forming an isolation region along sidewalls of the fin;
forming a dummy gate structure comprising a first dummy gate layer on a top surface and sidewalls of the stack of nanostructures and a second dummy gate layer on the first dummy gate layer, wherein the first dummy gate layer is on a first sidewall of the first nanostructure and a first sidewall of the second nanostructure;
doping exposed portions of the first dummy gate layer with first dopants; and
etching the exposed portions of the first dummy gate, wherein after etching the exposed portions of the first dummy gate layer, a width of the first dummy gate layer at an interface between the first dummy gate layer and the first sidewall of the first nanostructure in a top-down view is reduced, and a width of the first dummy gate layer at an interface between the first dummy gate layer and the first sidewall of the second nanostructure in the top-down view is reduced.

17. The method of claim 16, wherein the first dopants comprise a noble gas element.

18. The method of claim 16, further comprising doping the isolation region with the first dopants while doping the exposed portions of the first dummy gate layer with the first dopants.

19. The method of claim 18, wherein the first dopants are disposed at a depth less than 5 nm from a top surface of the isolation region.

20. The method of claim 16, wherein the first nanostructure comprises a first semiconductor material and the second nanostructure comprises a second semiconductor material different from the first semiconductor material.
